(19) United States
(12) Patent Application Publication
(10) Pub. No.: US 2008/0128594 A1
(43) Pub. Date: Jun. 5, 2008

(54) Backlight module with controlled output light intensity and driving method for same

(75) Inventors: Wen-Kai Lo, Miao-Li (TW); Tsung-Ping Liao, Miao-Li (TW)

Correspondence Address: WEI TE CHUNG;FOXCONN INTERNATIONAL, INC., 1650 MEMOREX DRIVE, SANTA CLARA, CA, 95050, US

(73) Assignee: INNOLUX DISPLAY CORP.

(21) Appl. No.: 11/999,089

(22) Filed: Dec. 3, 2007

(30) Foreign Application Priority Data
Dec. 1, 2006 (TW) 95144723

(51) Int. Cl. H03F 3/08; H05B 39/04

(52) U.S. Cl. 250/214 AL; 315/158

(57) ABSTRACT

An exemplary backlight module (1) includes a light source (11), a control circuit (15) and an ambient light detector (17). The ambient light detector is configured for detecting an intensity of ambient light beams and generating a corresponding current output to the control circuit. The control circuit is configured for modulating an intensity of light beams emitted by the light source according to predetermined staged modulating modes, the staged modulating modes corresponding to various amounts of the current.

### FIELD OF THE INVENTION

The present invention relates to backlight modules such as those used in liquid crystal displays (LCDs), and more particularly to a backlight module capable of adjusting its brightness in response to an intensity of ambient light beams. The present invention also relates to a driving method for such backlight module.

### GENERAL BACKGROUND

Liquid crystal displays are commonly used as displays for compact electronic apparatuses. This is because they not only provide good quality images with little power source consumption, but also they are very thin. The liquid crystal layer in a liquid crystal display does not emit any light beams itself. The liquid crystal has to be lit by a light source so as to clearly and sharply display text and images. Thus, a backlight module is generally needed for a liquid crystal display.

A standard backlight module has no means for controlling its brightness. Therefore a viewer may see displayed images of the liquid crystal display either easily or with difficulty, depending on the intensity of ambient light beams. Thus a better type of backlight module has been developed, with the backlight module being able to adjust its brightness according to the intensity of ambient light beams.

Referring to FIG. 7, this is a block diagram of a backlight module that has adjustable brightness. The backlight module 7 includes a light source 71, a power source 73, a control circuit 75, and an ambient light detector 77. The control circuit 75 includes a first input terminal 751, a second input terminal 752, and an output terminal 753. The first input terminal 751 of the control circuit 75 is coupled to the power source 73. The second input terminal 752 of the control circuit 75 is coupled to the ambient light detector 77. The output terminal 753 of the control circuit is coupled to the light source 71.

The power source 73 provides a basic driving current for the light source 71, and the basic driving current is firstly applied to the control circuit 75. The ambient light detector 77 is used to detect an intensity of ambient light beams, and accordingly generate a control signal. The control signal is applied to the control circuit 75. The control circuit 75 modulates the basic driving current according to the control signal, generates a modulated driving current, and then outputs the modulated driving current to the light source 71. The modulated driving current drives the light source 71 to shine with a desired brightness.

A process of operation of the backlight module 7 includes the following steps. Firstly, the ambient light detector 77 detects the intensity of the ambient light beams, and generates an analog control current accordingly. Referring to FIG. 8, the analog control current increases with an increase in the intensity of the ambient light beams. That is, when the intensity of the ambient light beams is low, the analog control current is low. When the intensity of the ambient light beams is great, the analog control current is great. Then, the ambient light detector 77 applies the analog control current to the control circuit 75.

Secondly, the control circuit 75 receives the analog control current from the ambient light detector 77 and a basic driving current from the power source 73. The control circuit 75 modulates the basic driving current according to the analog control current, and applies a modulated driving current to the light source 71. The modulated driving current increases with an increase in the analog control current. That is, when the analog control current is great, the modulated driving current is great. When the analog control current is low, the modulated driving current is low.

Thirdly, the light source 71 receives the modulated driving current and shines accordingly. Referring to FIG. 9, an intensity of light beams emitted by the light source 71 is linearly dependent on the modulated driving current. That is, when the modulated driving current is great, the intensity of the emitted light beams is great. When the modulated driving current is low, the intensity of the emitted light beams is low.

Therefore, the intensity of light beams emitted by the light source 71 is linearly dependent on the intensity of the ambient light beams.

However, when the intensity of the ambient light beams changes greatly, the brightness of the backlight module 7 accordingly changes greatly, and a viewer may see flickering of images displayed on the corresponding liquid crystal display. Furthermore, the backlight module 7 modulates its brightness according to the intensity of the ambient light beams all the time. The continuous modulating process shortens a working lifetime of the light source 7.

What is needed, therefore, is a backlight module that can overcome the above-described deficiencies. What is also needed is a driving method for such backlight module.

### SUMMARY

In one preferred embodiment, a backlight module includes a light source, a control circuit and an ambient light detector. The ambient light detector is configured for detecting an intensity of ambient light beams and generating a corresponding current output to the control circuit. The control circuit is configured for modulating an intensity of light beams emitted by the light source according to predetermined staged modulating modes. The modulating modes correspond to various amounts of the current.

Other novel features and advantages will become more apparent from the following detailed description when taken in conjunction with the accompanying drawings.

### BRIEF DESCRIPTION OF THE DRAWINGS

The components in the drawings are not necessarily drawn to scale, the emphasis instead being placed upon clearly illustrating the principles of the described embodiments. In the drawings, like reference numerals designate corresponding parts throughout various views, and all the views are schematic.

FIG. 1 is a block diagram of a backlight module according to a preferred embodiment of the present invention, the backlight module including an ambient light detector generating an analog current according to an intensity of ambient light beams, a memory generating a modulation signal, a control circuit generating a modulated driving current, and a light source.

FIG. 2 is a graph of the analog current generated by the ambient light detector of FIG. 1 versus intensity of ambient light beams.

FIG. 3 is a graph of the modulation signals generated by the memory of FIG. 1 versus intensity of ambient light beams.

FIG. 4 is a graph of the modulated driving current generated by the control circuit versus the modulation signals generated by the memory of FIG. 1.

FIG. 5 is a flowchart of operation of the backlight module of FIG. 1 at startup.

FIG. 6 is a flowchart of adjusting operation of the backlight module of FIG. 1 according to the intensity of ambient light beams.

FIG. 7 is a block diagram of a conventional backlight module, the backlight module including an ambient light detector, a control circuit, and a light source, the ambient light detector generating an analog control current, and the control circuit generating a modulated driving current.

FIG. 8 is a graph of the analog control current versus intensity of ambient light beams for the backlight module of FIG. 7.

FIG. 9 is a graph of intensity of light beams emitted by the light source versus the modulated driving current of the backlight module of FIG. 7.

### DETAILED DESCRIPTION OF PREFERRED EMBODIMENTS

Reference will now be made to the drawings to describe the preferred embodiments in detail.

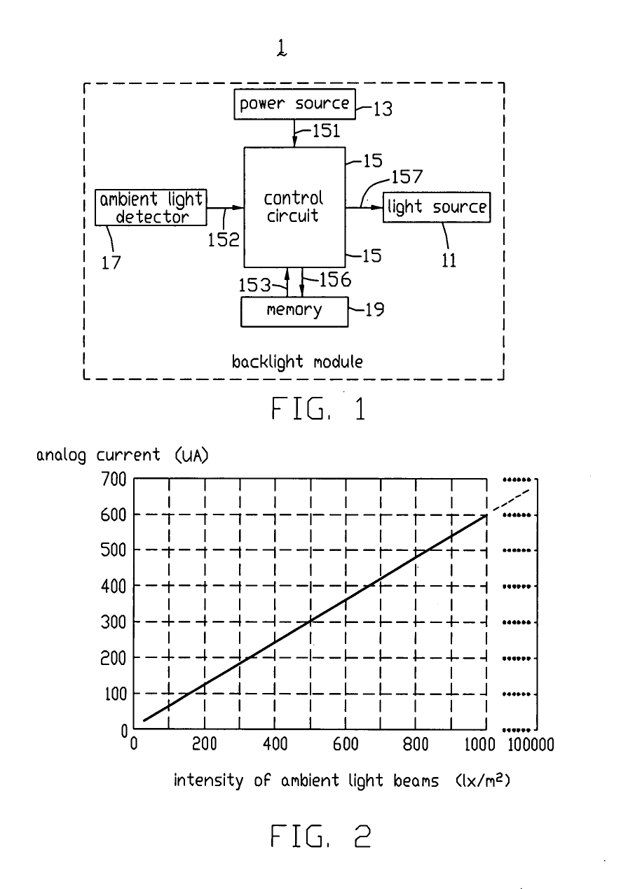

Referring to FIG. 1, a backlight module 1 includes a light source 11, a power source 13, a control circuit 15, an ambient light detector 17, and a memory 19. The control circuit 15 includes a first input terminal 151, a second input terminal 152, a third input terminal 153, a first output terminal 156, and a second output terminal 157. The power source 13 includes an output terminal (not labeled) coupled to the first input terminal 151 of the control circuit 15. The ambient light detector 17 includes an output terminal (not labeled) coupled to the second input terminal 152 of the control circuit 15. The memory 19 includes an output terminal (not labeled) coupled to the third input terminal 153 of the control circuit 15, and an input terminal (not labeled) coupled to the first output terminal 156 of the control circuit 15. The light source 11 includes an input terminal (not labeled) coupled to the second output terminal 157 of the control circuit 15.

The power source 13 is used to generate a basic driving current for driving the light source 11. The basic driving current is firstly applied to the control circuit 15. The ambient light detector 17 is used to detect an intensity of the ambient light beams, and generate an analog current according to the intensity of the ambient light beams. Referring to FIG. 2, the analog current increases with an increase in the intensity of the ambient light beams. The ambient light detector 17 can be a light-sensitive resistance, a semiconductor element, or an optical integral circuit.

The memory 19 can be an erasable programmable read-only memory (EPROM), such as an electrically erasable programmable read-only memory (EEPROM). The memory 19 includes a look-up table (not shown). The look-up table includes four modulation signals: modulation signal 1, modulation signal 2, modulation signal 3, and modulation signal 4. Each modulation signal corresponds to a respective range of intensities of the ambient light beams.

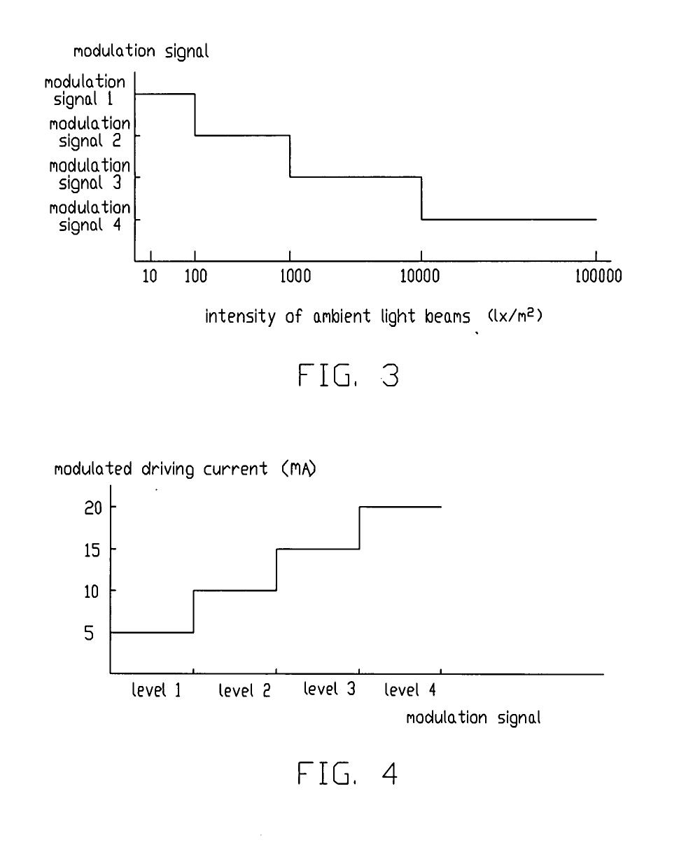

Referring to FIG. 3, modulation signal 1 corresponds to intensities of ambient light beams in the range from 10 lx/m² to 100 lx/m². Modulation signal 2 corresponds to intensities of ambient light beams in the range from 100 lx/m² to 1000 lx/m². Modulation signal 3 corresponds to intensities of ambient light beams in the range from 1000 lx/m² to 10000 lx/m². Modulation signal 4 corresponds to intensities of ambient light beams in the range from 10000 lx/m² to 100000 lx/m². The control circuit 15 can look up a suitable modulation signal from the look-up table in the memory 19 corresponding to the intensity of ambient light beams.

The control circuit 15 is used to modulate the basic driving current according to the modulation signal obtained from the look-up table in the memory 19, and apply a modulated driving current to the light source 11. The modulated driving current drives the light source 11 to shine with a desired brightness. The light source 11 can for example be a plurality of light emitting diodes (LEDs).

Referring to FIG. 4, when the control circuit 15 obtains modulation signal 1 from the look-up table, it modulates the basic driving current to a modulated driving current of 5 mA. When the control circuit 15 obtains modulation signal 2 from the look-up table, it modulates the basic driving current to a modulated driving current of 10 mA. When the control circuit 15 obtains modulation signal 3 from the look-up table, it modulates the basic driving current to a modulated driving current of 15 mA. When the control circuit 15 obtains modulation signal 4 from the look-up table, it modulates the basic driving current to a modulated driving current of 20 mA.

Referring to FIG. 5, when the backlight module 1 is started up, a preliminary operation is executed as follows. In step S11, the power source 13 is switched on. In step S12, the control circuit 15 receives a basic driving current from the power source 13, and simultaneously looks up a modulation signal in the look-up table. The modulation signal corresponds to an intensity of the ambient light beams at the time the backlight module 1 was last switched off. In step S13, the control circuit 15 modulates the basic driving current according to the modulation signal, and applies the modulated driving current to the light source 11. Therefore, the backlight module 1 shines with a brightness the same as the brightness at the time the backlight module 1 was last switched off.

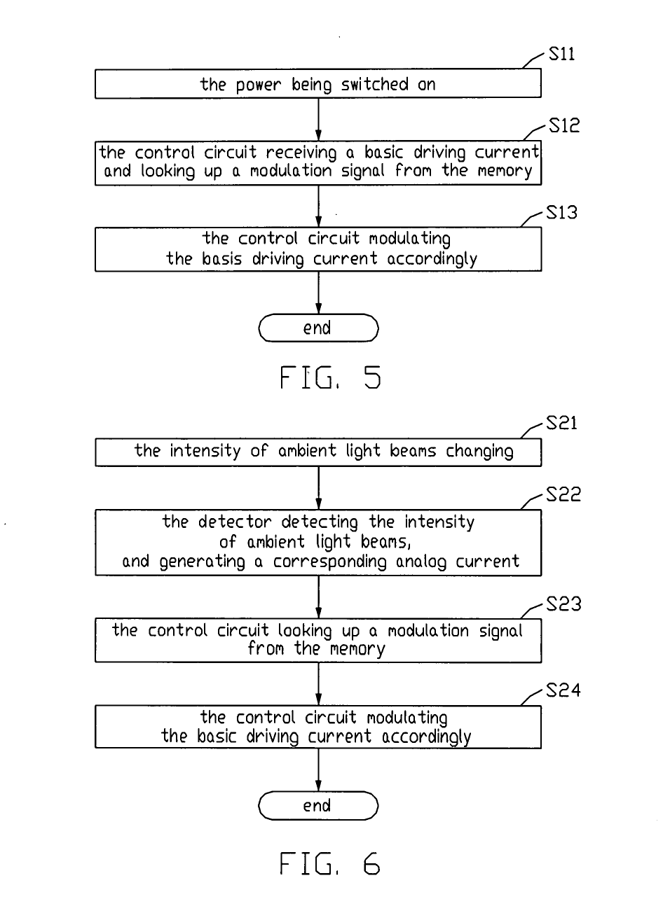

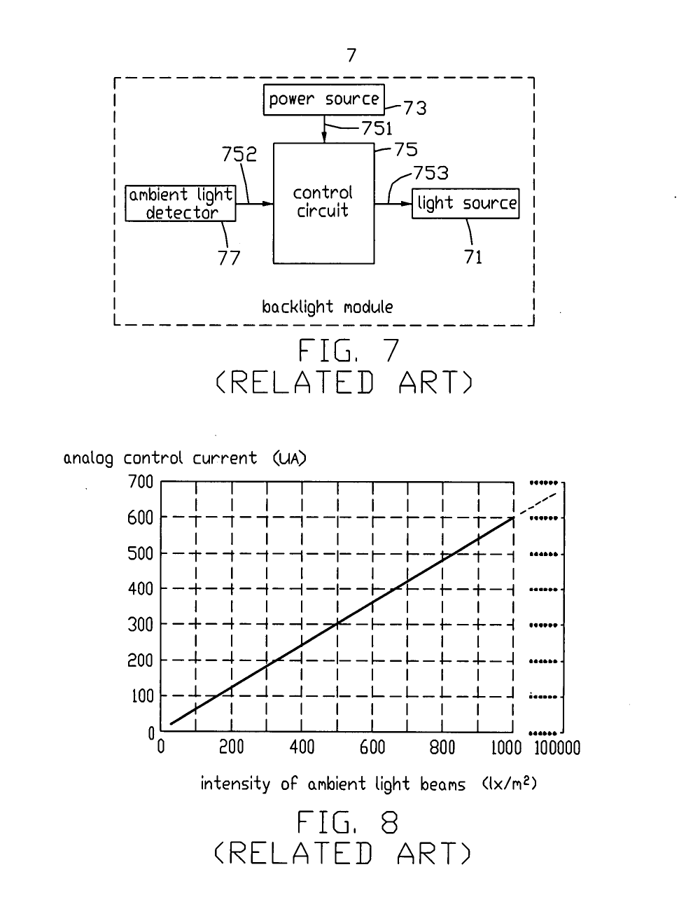

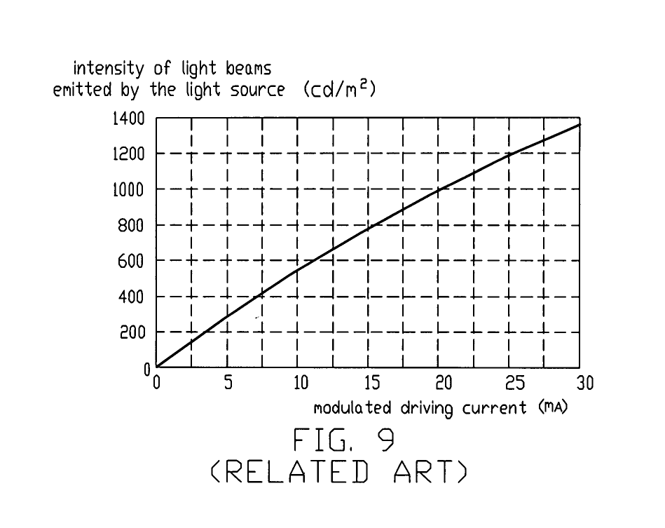

Referring to FIG. 6, an exemplary process for modulating the brightness of the backlight module 1 includes the following steps. In step S21, the intensity of ambient light beams changes. In step S22, the ambient light detector 17 detects the new intensity of the ambient light beams, and generates a corresponding analog current, and outputs the analog current to the control circuit 15 accordingly. For example, the analog current increases with an increase in the intensity of the ambient light beams.

In step S23, the control circuit 15 looks up a modulation signal from the memory 19 according to the intensity of the ambient light beams.

In step S24, the control circuit 15 modulates the basic driving current according to the modulation signal obtained. The modulated driving current is applied to the light source 11. Thus, the light source 11 shines with a desired level of brightness corresponding to the intensity of the ambient light beams.

Unlike conventional backlight modules, the backlight module 1 does not modulate its brightness linearly with changes in the intensity of ambient light beams. Rather, the backlight module 1 modulates its brightness according to staged modulating modes. That is, the backlight module 1 modulates its brightness among a limited number of dicrete brightness levels, each brightness level corresponding a respective range of intensities of ambient light beams. Thus, when the intensity of the ambient light beams changes only within one of the ranges, the backlight module 1 does not modulate its brightness. Therefore, a display performance of the backlight module 1 is stable. Furthermore, because the backlight module 1 need not change its brightness all the time with changes in the intensity of the ambient light beams, the working lifetime of the backlight module 1 is prolonged.

Further or alternative embodiments may include the following. In one example, a backlight module can have more than four modulation signals, or less than four modulation signals. Each modulation signal corresponds to a respective selected range of intensities of ambient light beams. In another embodiment, modulated driving currents corresponding to different modulation signals can be set at other values as needed.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A backlight module comprising:
a light source,
a control circuit, and
an ambient light detector configured for detecting an intensity of ambient light beams and generating a corresponding current output to the control circuit, the control circuit configured for modulating an intensity of light beams emitted by the light source according to predetermined staged modulating modes, the staged modulating modes corresponding to various amounts of the current.

2. The backlight module as claimed in claim 1, further comprising a memory comprising a look-up table, the look-up table comprising a plurality of modulation signals, each modulation signal corresponding to a respective range of intensities of ambient light beams.

3. The backlight module as claimed in claim 2, wherein the memory is an erasable programmable read-only memory.

4. The backlight module as claimed in claim 2, wherein the memory is an electrically erasable programmable read-only memory.

5. The backlight module as claimed in claim 2, wherein the control circuit is further configured to generate a plurality of modulated driving currents, each modulated driving current corresponding to a modulation signal of the look-up table, respectively.

6. The backlight module as claimed in claim 2, wherein the look-up table comprises four modulation signals, each modulation signal corresponding to a respective range of intensities of ambient light beams.

7. The backlight module as claimed in claim 6, wherein the modulation signals comprises a modulation signal 1, a modulation signal 2, a modulation signal 3 and a modulation signal 4.

8. The backlight module as claimed in claim 7, wherein the modulation signal 1 corresponds to intensities of ambient light beams ranged from 10 lx/m² to 100 lx/m², the modulation signal 2 corresponds to intensities of ambient light beams ranged from 100 lx/m² to 1000 lx/m² , the modulation signal 3 corresponds to intensities of ambient light beams ranged from 1000 lx/m² to 10000 lx/m², and the modulation signal 4 corresponds to intensities of ambient light beams ranged from 10000 lx/m² to 100000 lx/m².

9. The backlight module as claimed in claim 1, further comprising a power source configured for providing a basic driving current to drive the light source.

10. The backlight module as claimed in claim 1, wherein the ambient light detector can be one of the group consisted of light-sensitive resistances, semiconductor elements and optical integral circuits.

11. A driving method for a backlight module, the backlight module comprising a light source, a control circuit and an ambient light detector, the control circuit electrically connecting the light source with the ambient light detector, the driving method comprising:
the ambient light detector detecting an intensity of ambient light beams, and
generating a corresponding basic current output to the control circuit;
the control circuit generating a modulated driving current according to the amount of the basic current, the modulated driving current being of a predetermined mode corresponding to a predetermined range of amounts of current that the basic current falls in;
the control circuit applying the modulated driving current to the light source; and
the modulated driving current driving the light source to emit light.

12. The driving method as claimed in claim 11, further comprising a power source, the power source generates a basic driving current to the control circuit, the control circuit modulating the basic driving current and generating the modulated driving current.

13. The driving method as claimed in claim 11, wherein the current generating by the ambient light detector increases with an increase of the intensity of the ambient light beams.

14. The driving method as claimed in claim 11, further comprising a memory, the memory comprising a plurality of the modulation signals, each modulation signal corresponding to a range of intensities of ambient light beams.

15. The driving method as claimed in claim 14, wherein the control circuit looks up a modulation signal from the memory according to the current from the ambient light detector, and then generates the modulated driving current.

16. The driving method as claimed in claim 14, wherein the modulation signals comprises a modulation signal 1, a modulation signal 2, a modulation signal 3 and a modulation signal 4.

17. The driving method as claimed in claim 16, wherein the modulation signal 1 corresponds to intensities of ambient light beams ranged from 10 lx/m² to 100 lx/m², the modulation signal 2 corresponds to intensities of ambient light beams ranged from 100 lx/m² to 1000 lx/m² , the modulation signal 3 corresponds to intensities of ambient light beams ranged from 1000 lx/m² to 10000 lx/m², and the modulation signal 4 corresponds to intensities of ambient light beams ranged from 10000 lx/m² to 100000 lx/m².
